(19) United States
(12) Patent Application Publication
(10) Pub. No.: US 2003/0227759 A1
(43) Pub. Date: Dec. 11, 2003

(54) Electromagnetic interference gasket

(76) Inventor: Stephen Paul Haworth, Wokingham (GB)

Correspondence Address: B. Noel Kivlin, Conley, Rose, & Tayon, P.C., P.O. Box 398, Austin, TX, 78767, US

(21) Appl. No.: 10/166,528

(22) Filed: Jun. 10, 2002

(51) Int. Cl. H05K 7/14; H05K 7/18

(52) U.S. Cl. 361/800

(57) ABSTRACT

A gasket (50) provides an EMI shield between part of a frame (1) of an electronics assembly and a component (2) of the assembly. The gasket is formed from a resiliently deformable electrically conductive sheet e.g. from spring stainless steel, and has an array of resiliently deformable fingers that extends along an edge region thereof for contacting either the frame (1) and the component, and a plurality of clips (60) that can engage corresponding attachment elements in the component or the frame respectively to form a mechanical connection therewith. The gasket is easy to locate in position and does not require the use of adhesive to retain it in position.

### BACKGROUND OF THE INVENTION

The present invention relates to electromagnetic interference (EMI) gaskets, and to electronics assemblies, containing such gaskets. Typical of such assemblies are those that will be located in racks, for example nineteen inch, twenty three inch racks or metric racks for location in cabinets. Such assemblies may, for instance, be employed as servers in local area networks (LANs) wide area networks (WANs) for a variety of telecommunications functions or other operations such as database management or as internet servers.

Such an assembly will typically comprise a supporting frame that houses a motherboard or backplane and a number of daughterboards or module cards that extend in planes generally perpendicular to the plane of the motherboard and which are connected to the motherboard by connectors, e.g. high density connectors, so that the daughterboards can simply be located on guides and pushed toward the motherboard in order to connect them to it.

The assembly will normally include a number of components such as power supply units, power distribution units, disc drives, tape drives and the like, that are often in modular form and are inserted into recesses in the frame from the proximal end thereof. In such assemblies it is often necessary to protect the system from electromagnetic interference by providing a gasket in the recesses for the modular components, for example at the distal end of the recess, where only restricted access is available.

A number of conventional EMI gaskets such as so-called “finger strips” or other gaskets are available based on compressible electrically conductive materials, but none have proved satisfactory in this environment. In particular, it would be desirable to have an EMI gasket that can be fitted into a deep recess, that makes good electrical contact between the component and those parts of the frame deep within the recess, and which is relatively easy to install and remove if damaged. In addition, it would be desirable for the gasket not to become detached when the modular component is removed from the assembly or lose performance.

### SUMMARY OF THE INVENTION

According to one aspect, the present invention provides a gasket for providing an EMI shield between part of a frame of an electronics assembly and a component of the assembly, the gasket being formed from a resiliently deformable electrically conductive sheet having an array of resiliently deformable fingers that extends along an edge region thereof for contacting one of the part of the frame and the component, and a plurality of clips that can engage corresponding attachment elements in the other of the part of the frame and the component to form a mechanical connection therewith.

Normally the fingers will extend out of the plane of the sheet and are forced to move toward the plane when the component is installed in the assembly thereby ensuring a good electrical contact between the gasket and the component or the frame. For example the fingers may have a sloping central portion which extends from the flat peripheral region of the gasket at an angle of 20 to 50° to the plane of the gasket followed by a tip that lies in a plane parallel to that of the gasket. When a modular component is inserted into its recess in the assembly, the gasket can be squeezed almost flat so that it occupies a thickness not much greater than that of the sheet from which it is formed. The fingers need not all be oriented in the same direction along any peripheral region of the gasket. Some fingers could, for example, be oriented in an opposite direction to others, for example alternate fingers could be oriented in opposite directions. The fingers could be oriented toward the centre of the gasket or they could be oriented outwardly toward the edge thereof. The fingers may be formed in the outer edge of the peripheral region or in an inwardly oriented edge, that is to say, where the gasket has a central aperture, they may be formed along the edge of the central aperture. Alternatively or in addition, they may be formed within separate apertures or cut-outs in the peripheral region.

If all the fingers extend out of the plane of the sheet of metal on one side of the gasket, it is convenient for the clips to extend out of the other side of the sheet from which the gasket is formed so that the clips can easily engage the corresponding engagement elements easily.

The clips may be arranged so that they can be engaged with, or disengaged from, the corresponding engagement elements by sliding in the plane of the sheet. In such an arrangement the clips typically will have a central part that extends out of the plane of the sheet, for example substantially perpendicular thereto, and spaces end portions of the clips from the plane of the sheet by about 1 to 2 mm. The corresponding attachment elements may, for example, be recesses or holes in the frame which the clips can engage, or they may themselves be in the form of clips that are oppositely oriented in order to be grasped by the clips of the gasket.

The clips may be arranged in a number of different arrangements. For example all the clips could be oriented in the same direction so that movement of the entire gasket in one direction by a few millimetres will engage it with the frame or disengage it from the frame. With such an arrangement, however, it may be necessary to include a detent or other element to prevent inadvertent movement of the gasket so as to disengage it, for example by ensuring that frictional resistance to such movement is sufficient to prevent the movement. In an alternative arrangement, at least one of the clips may be oriented in the opposite direction to the others so that movement of the gasket with respect to the frame in a direction tending to disengage some of the clips will tend to bring other clips into engagement with their corresponding attachment elements. Thus, for example, the gasket may be provided with clips that are located on a pair of opposite peripheral regions thereof so that they can be disengaged from the corresponding attachment elements by deforming the gasket into an arcuate configuration. In order to engage the gasket with, for example, a wall or bulkhead at the distal end of a recess, the gasket is bent slightly or bowed in order to bring the clips nearer to one another along a straight line so that they can be placed in alignment with holes in the wall and on release of the gasket, will engage the holes. The gasket can easily be removed, simply by pulling the parts thereof between the oppositely directed clips in a direction toward the proximal end of the recess whereupon the gasket will bend or bow, and the clips will slide toward one another out of engagement with the holes.

The gasket may be provided with one or more apertures in a central region thereof (i.e. other than the peripheral region) to allow connectors, cabling, other modules or anything else to extend therethrough. Indeed, the gasket may often simply be in the form of a frame defining the peripheral region and one large central aperture. The gasket may have a size to fit any internal recess in the enclosure or it may be somewhat smaller than the recess. Provided the aperture is sufficient to allow the enabling or connectors to extend therethrough, and the gasket will contact the other conductive surfaces for example of the module and any partition it is located on, it will prevent passage of EMI radiation into other regions of the assembly. Alternatively, the gasket may be in strip form of indeterminate length and is cut to length before use. A number of separate gaskets may be used together to form a rectangular array. As a further alternative, two “L”-shaped gaskets may be employed to form a rectangular gasket.

According to another aspect, the invention provides a frame for an electronics assembly which has at least one recess having a proximal end into which a component of the assembly can be inserted and a distal end having a gasket for providing an EMI shield between the component and the frame, the gasket being formed from a resiliently deformable electrically conductive sheet and having an array of resiliently deformable fingers that extends along can edge region thereof for contacting the component and being mechanically attached to the frame by means of a plurality of clips in the gasket or in the frame that engage the frame or the gasket respectively.

In the frame according to this aspect of the invention, the clips may be provided in the frame, for example in a wall or bulkhead at the distal end of the recess, and may engage corresponding parts of the gasket, or the clips may be located in the gasket as described above. If the clips are located on the frame, they may be oriented toward one another and either engage corresponding elements such as holes in the gasket or engage the outer peripheral edge of the gasket. Whatever arrangement is chosen, the gasket can easily be engaged or disengaged by bending it into an arcuate form.

According to yet another aspect, the invention provides an electronics assembly which comprises a frame with at least one recess that contains a component of the assembly, and a gasket located at a distal end of the recess for providing an EMI shield between the component and the frame, the gasket being formed from a resiliently deformable electrically conductive sheet and having an array of resiliently deformable fingers extending along an edge region thereof for contacting the component or the frame, the gasket being mechanically attached to the frame or to the component by means of a plurality of clips in the gasket or in one of the frame and the component that engage corresponding engagement elements in the other of the frame and the component or in the gasket respectively.

In the assembly according to this aspect of the invention, the gasket may be mechanically attached to the frame by means of clips in the gasket or in the frame and corresponding engagement elements in the frame or the gasket respectively. Alternatively, it may be mechanically attached to the component, for example one of the electronics modules, by means of clips in the gasket or in the component and corresponding engagement elements in the component or the gasket respectively, so that the gasket will remain attached to the component and will be removed from the assembly along with the component. Such an arrangement has the advantage of ease of attachment of the gasket, but will require a service engineer or other person to check that the gasket is located on the module whenever a module is inserted in the assembly.

If the gasket is mechanically attached to the frame of the assembly, it can be as described above, for example with clips provided on opposite peripheral regions thereof that engage corresponding elements in the frame.

The EMI gasket may be formed to any of a number of different designs that are specific to design of the recess in the frame of the assembly and to the module. The gasket may have the resiliently deformable fingers thereon arranged with a spacing in the range of from about 0.5 to 3 cm although smaller and larger spacings are possible. It is also possible to dispense with the fingers in a number of places on the gasket, and to provide attachment clips at those places by bending the sheet metal from which the gasket is formed in a direction opposite to that of the fingers.

### BRIEF DESCRIPTION OF THE DRAWINGS

Embodiments of the present invention will now be described in detail with reference to the accompanying drawings, in which corresponding parts are given like reference numbers. In the drawings:

FIG. 1 is an isometric view of a typical electronics assembly in which a gasket according to the invention may be employed;

FIG. 2 is a section through part of the assembly showing insertion of a module therein;

FIG. 3 is a perspective view of an internal wall in the assembly of FIGS. 1 and 2, showing a gasket according to the invention;

FIG. 4 is a perspective view of part of the wall of FIG. 3 on an enlarged scale;

FIG. 5 is a perspective view of part of the wall of FIG. 3 from the opposite side thereof;

FIG. 6 is a schematic edge view of part of the wall of FIG. 3 during installation of the gasket; and

FIG. 7 is an exploded view of another embodiment of the invention together with part of an internal wall of an electronics assembly.

### DESCRIPTION OF PARTICULAR EMBODIMENTS

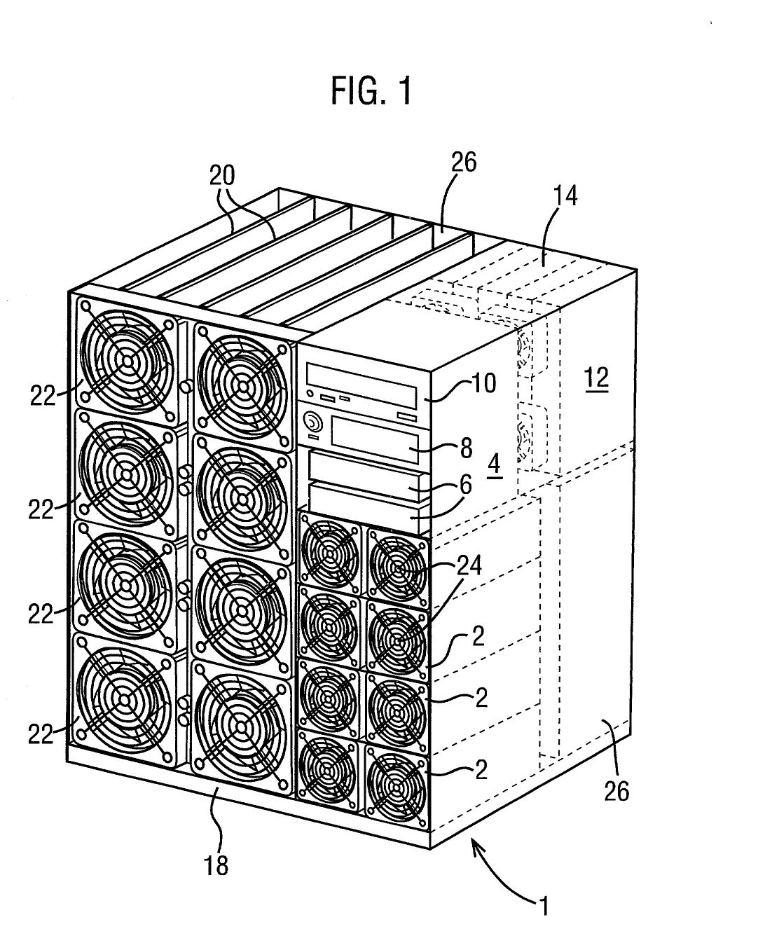

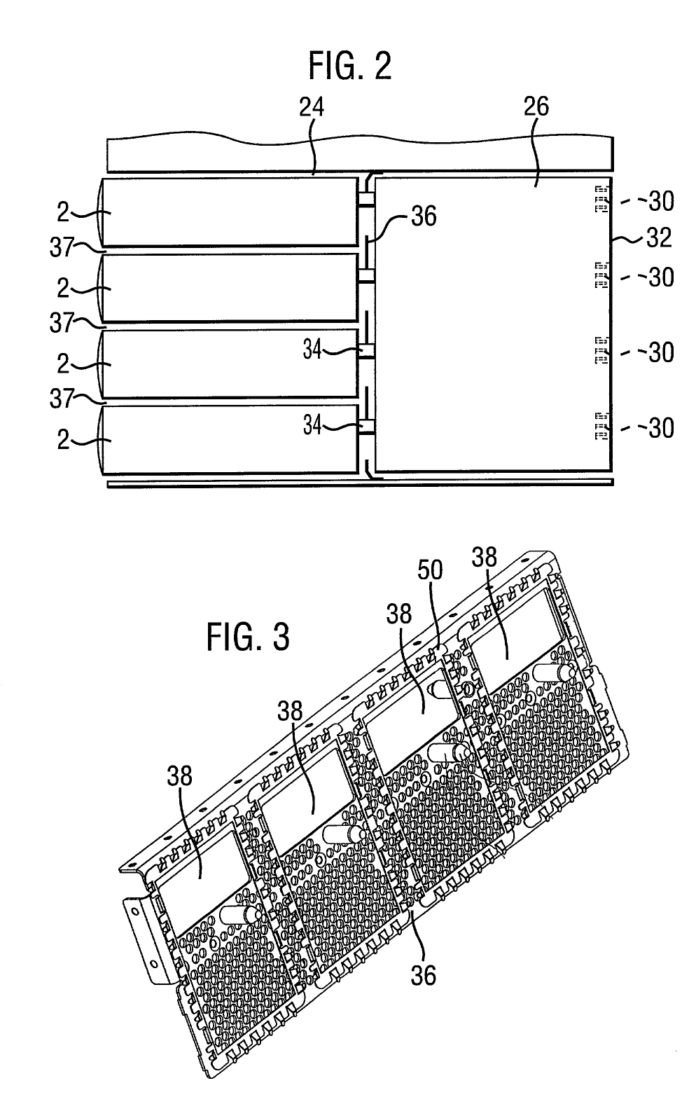

Referring now to the drawings, in which like reference numerals are used to designate corresponding elements, FIG. 1 shows an assembly according to one embodiment of the invention that forms part of a server that may be employed for a number of services, for example as part of a local area network (LAN) or for other telecommunications purposes, and is designed to fit into, for example a nineteen inch rack to be located in an electronics cabinet. Other sizes may alternatively be employed for example to fit into 23 inch or metric racks. The assembly comprises a frame 1 in which the various components are located. The frame 1 contains a part 4 that contains hard disk drives 6, a tape drive 8 and a CD-ROM or digital video disc drive 10, and a part 12 that contains a number of I/O cards 14. A motherboard is located within the frame in a horizontal plane at the bottom of the frame in a tray-shaped holder 18, and a number of daughterboards 20 are arranged next to each other in vertical planes above the motherboard and to the side of the power modules 2. The daughterboards may serve any of a number of purposes, for example having CPUs or may be repeater boards etc. Finally, a number of fans 22 are provided in an array at the front of the frame in order to blow air through the assembly between the daughterboards 20 for cooling.

Four power supply modules 2 are provided in a part 24 of the frame together with a power inlet connection module 26 that takes a.c. power from the mains and distributes the power to each of the power supply modules. Each power supply module 2 is capable of receiving a.c. mains voltage via plug, transforming, rectifying and smoothing it and supplying output d.c. voltage through connector, located on the same side of the power supply module as the power input plug, to a common power distribution board and delivering the power to the motherboard via connector. The system employs a degree of redundancy with the power supply modules 2 so that one or two of the modules can be removed for servicing or repair while the system can still operate.

Mains a.c. power is supplied to the power supply modules 2 by means of the power inlet connection module 26. The power inlet connection module 26 has four mains plugs 30 on its rear surface 32 for connection to up to four ring mains via standard cabling (not shown) and can channel the current to any of four IEC 320 sockets 34 into which the power supply modules 2 are plugged.

The frame 1 is provided with an internal wall or bulkhead 36 that separates the location at the rear of the frame for receiving the power inlet connection module 26 from four recesses 37 for receiving the power supply modules 2, and which is provided with four apertures 38 through which the bodies of the sockets can extend to the other side of the wall. The four rectangular apertures 38 in the wall are large enough to receive not only the sockets 37 of the power inlet connection module 26, but also the four low voltage d.c. power connectors 27 of the power supply modules which extend to the rear side of the wall at a position adjacent to the location for the power inlet connection module. At the rear side of the wall 36, the frame is also provided with a pair of vertically extending card guides (not shown) for receiving the power distribution circuit board 28 that can be introduced from above and slid vertically downwards into connection with the motherboards. When inserted, the power distribution circuit board will be next to, and in a plane parallel to the plane of power inlet connection module 26.

On the side of the wall 36 facing the front of the assembly, four EMI gaskets 50 are located, one gasket being located within each of the recesses 37 for forming a contact between the wall 36 and each of the power supply units 2 inserted into the recesses 37.

Each gasket 50 may be formed from resiliently deformable electrically conductive material, for example spring stainless steel or from beryllium copper. Other suitable materials such as metal coated plastics may be used to form the sheet as well. The sheet has a generally rectangular shape which may correspond in size to the transverse dimensions of the recesses 38 and of the power supply modules that are inserted therein or may be somewhat smaller. The gaskets 50 may each have an aperture therein that occupies most of the area of the gasket so that only a border remains.

A number of resiliently deformable fingers 52 are arranged along each outward facing edge of the gasket, each finger tapering in width from approximately 3 mm at its base to a width of approximately 2 mm near its apex. The fingers are formed by cutting or stamping the appropriate outline of the finger from the sheet and then bending the outline out of the plane of the sheet to form an inclined part 54 of the finger which extends at an angle of approximately 30° to the plane of the gasket. Each finger has a tip 56 that is bent back so that it is substantially parallel to the plane of the gasket and extends for 1 to 2 mm from the end of the inclined part. The fingers are generally arranged at a repeat spacing of about 1 cm.

On the two opposed longer edges of the gasket, but not on the two opposed shorter edges, four clips 60 are located, two on each edge. The clips are formed by cutting or stamping an appropriate profile from the sheet from which the gasket is made, and bending the profile to the opposite side of the gasket from the fingers so that a middle part 62 thereof is generally perpendicular to the plane of the gasket or inclined thereto at an angle of at least 60°, and a tip 64 is bent in the opposite direction to be substantially parallel to the plane of the gasket. The clips 60 on one edge of the gasket 50 are oriented in a direction opposite to the clips on the opposed edge, in this case by being joined to the edge region of the gasket 50 at their inward ends so that if the gasket is moved along a surface in its own plane, those clips on the leading edge will engage any corresponding parts.

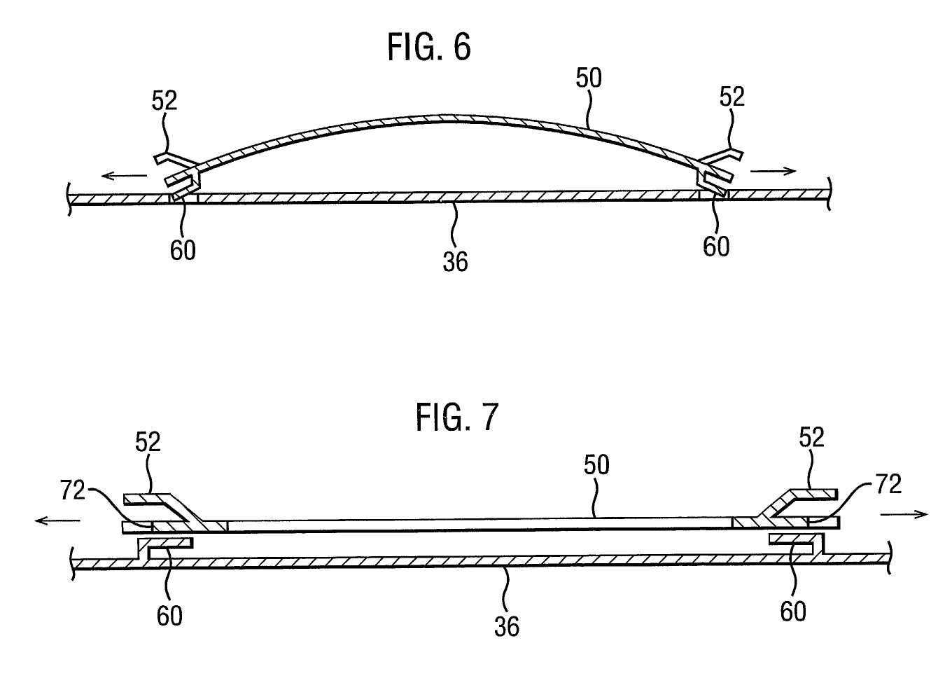

The wall 36 is provided with four small apertures 66 for receiving the clips 60. The gasket may be mounted on the wall 36 simply by placing it against the wall with the clips 60 in contact therewith and sliding the gasket over the wall until the clips 60 on the leading edge of the gasket engage the corresponding apertures 66 in the wall. The trailing edge of the gasket is then pushed toward the leading edge causing the gasket to bow into an arcuate shape until the tips 64 of the clips 66 on the trailing edge of the gasket are in register with corresponding apertures in the wall. Release of the trailing edge of the gasket 50 as shown in FIG. 6 will allow the gasket to relax into a planar configuration causing the trailing edge to move in the opposite direction (in the direction of the arrow) and allowing the clips 60 thereon to engage the apertures 66 in the wall 36.

When the gaskets 50 are held on the wall 36 in this manner, the power supplies 2 can be inserted into the recesses 37 into engagement with the connectors on the power inlet distribution module and until the distal ends of the power supply modules 2 abut the tips 56 of the fingers 52. The dimensions of the power supply modules and the recesses 37 in the frame are adjusted so that the distal end of the module 2 will force the fingers 52 toward the plane of the gasket 50 to some degree against their bias, thereby ensuring a good electrical contact around the entire periphery of the gasket.

If at any time the gasket needs to be removed, for example because of damage, one of the edge regions thereof that is provided with the clips 60 is moved toward the opposed edge region so that the gasket 50 bows into an arcuate shape along the two edge regions that do not contain any clips, and the clips 60 move out of engagement with the apertures 66. The remaining two engaged clips are then moved out of engagement with their apertures 60 by sliding the gasket along the surface of the wall 36. Alternatively, the mid points of the adjacent edge regions that are not provided with clips 60 may be pulled toward the proximal end of the recess, thereby causing one or both edge regions that is provided with clips 60 to move toward the other and allow the clips to be disengaged from the apertures.

In this way, the gasket 50 can be removed easily from the wall when required, but is unlikely to become accidentally dislodged. In addition, because the gasket is attached to the wall purely mechanically, it can, unlike gaskets relying on adhesives, be detached and reattached a large number of times.

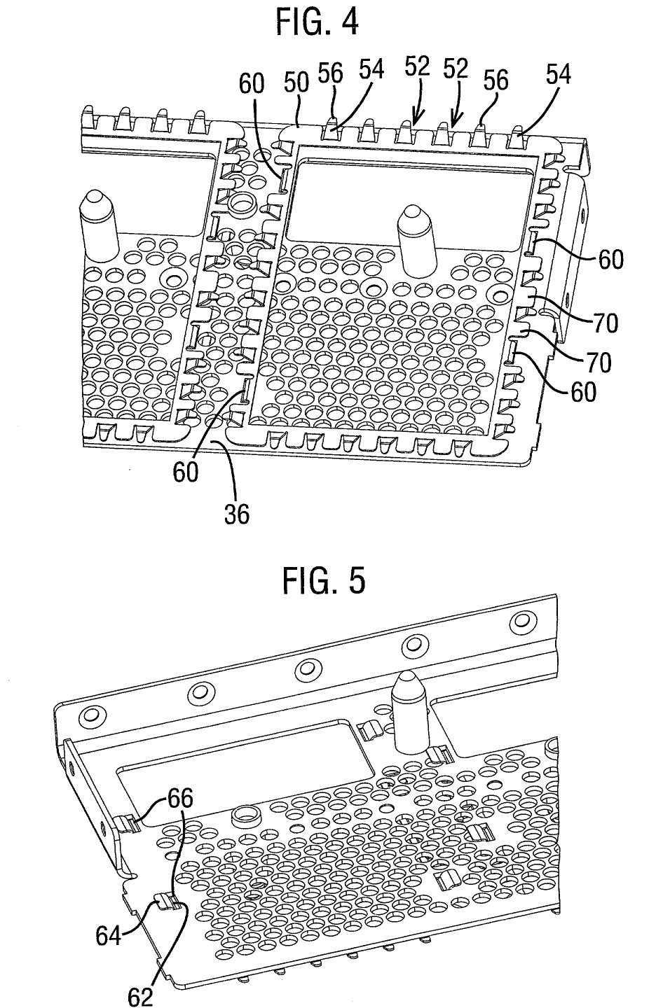

As can be seen from FIG. 4, a number of blank flat areas 70 may be provided for forming clips in different positions from the clips 60 if required.

FIG. 7 shows an alternative form of gasket 50 according to the invention that can be installed on an internal wall 36 of an electronics assembly. This form of gasket is generally similar to the gasket shown in FIG. 4 and comprises a generally planar rectangular structure having an array of fingers 52 for contacting an electronics component to be inserted into a recess in a frame of the assembly.

This gasket, however, has a number of edges 72 for receiving clips 60 that are located on the internal wall 36. The clips 60 in this embodiment are inwardly directed so that they face one another rather than facing away from each other as shown in FIG. 4. In order to install the gasket, it is simply placed on the internal wall 36 and slid along the wall until the clips 60 engage the edges 72 on one side of the gasket. The opposite edge region of the gasket is then moved toward that edge region that engages the clips 60 thereby causing the gasket to bow outwardly and allowing the clips 60 to engage the edges on the opposite edge region of the gasket. On release of the gasket, all the edges 72 will be engaged by the clips and the gasket will be held in place. The gasket can be removed simply by sliding one edge region toward the other out of engagement with the clips 60 and releasing it.

The gasket is not restricted to use in an electronics assembly as described herein, but may be employed with partition walls, whether internal or external of any form of assembly where protection from EMI is required.

The scope of the present disclosure includes any novel feature or combination of features disclosed therein either explicitly or implicitly or any generalisation thereof irrespective of whether or not it relates to the claimed invention or mitigates any or all of the problems addressed by the present invention. The applicant hereby gives notice that new claims can be formulated to such features during the prosecution of this application or of any such further application derived therefrom. In particular, with reference to the appended claims, features from dependent claims can be combined with those of the independent claims and features from respective independent claims can be combined in any appropriate manner and not merely in the specific combinations enumerated in the claims.

1. A gasket for providing an EMI shield between part of a frame of an electronics assembly and a component of the assembly, the gasket being formed from a resiliently deformable electrically conductive sheet having an array of resiliently deformable fingers that extends along an edge region thereof for contacting one of the part of the frame and the component, and a plurality of clips that can engage corresponding attachment elements in the other of the part of the frame and the component to form a mechanical connection therewith.

2. A gasket as claimed in claim 1 which is generally planar.

3. A gasket as claimed in claim 1, wherein the fingers extend out of the plane of the electrically conductive sheet and are deformable toward the plane when a component is installed in the assembly.

4. A gasket as claimed in claim 3, wherein all the fingers extend out of the plane of the electrically conductive sheet on one side of the gasket and the clips extend out of the plane of the sheet on the other side of the gasket.

5. A gasket as claimed in claim 1, wherein the clips are arranged so that they can be engaged with, or disengaged from, corresponding engagement elements by sliding in the plane of the electrically conductive sheet.

6. A gasket as claimed in claim 1, wherein the clips are located on a pair of opposite peripheral regions of the gasket and can be disengaged from the corresponding attachment elements by deforming the gasket into an arcuate configuration.

7. A gasket as claimed in claim 1, wherein the resiliently deformable fingers are arranged at a spacing between centres of fingers, or the space between two fingers in the range of from about 0.5 to about 3 cm.

8. A gasket as claimed in claim 1, having one or more apertures in a central region thereof.

9. A gasket as claimed in claim 1 which is formed from a metal.

10. A gasket as claimed in claim 9, which is formed from spring stainless steel or from beryllium copper.

11. A frame for an electronics assembly which has at least one recess having a proximal end into which a component of the assembly can be inserted and a distal end having a gasket for providing an EMI shield between the component and the frame, the gasket being formed from a resiliently deformable electrically conductive sheet and having an array of resiliently deformable fingers that extends along can edge region thereof for contacting the component and being mechanically attached to the frame by means of a plurality of clips in the gasket or in the frame that engage the frame or the gasket respectively.

12. A frame as claimed in claim 11, wherein the gasket is generally planar.

13. A frame as claimed in claim 11, wherein the fingers extend out of the plane of the sheet of metal and are deformable toward the plane when the component is installed in the frame.

14. A frame as claimed in claim 11, wherein the clips are located on the gasket and engage corresponding attachment elements on the frame.

15. A frame as claimed in claim 11, wherein the clips are arranged so that the gasket and the frame can be disengaged from one another by relative sliding in the plane of the sheet of metal.

16. A frame as claimed in claim 11, wherein the clips are located on a pair of opposite peripheral regions of the gasket and can be disengaged from corresponding engagement elements by deforming the gasket into an arcuate configuration.

17. A frame as claimed in claim 11, wherein the gasket has one or more apertures in a central region thereof.

18. A frame as claimed in claim 11, wherein the resiliently deformable fingers are arranged at a spacing in the range of about 0.5 to 3 cm.

19. A frame as claimed in claim 11, wherein the gasket is formed from a metal.

20. An electronics assembly which comprises a frame with at least one recess that contains a component of the assembly, and a gasket located at a distal end of the recess for providing an EMI shield between the component and the frame, the gasket being formed from a resiliently deformable electrically conductive sheet and having an array of resiliently deformable fingers extending along an edge region thereof for contacting the component or the frame, the gasket being mechanically attached to the frame or to the component by means of a plurality of clips in the gasket or in one of the frame and the component that engage corresponding engagement elements in the other of the frame and the component or in the gasket respectively.

21. An assembly as claimed in claim 20, wherein the gasket is generally planar.

22. An assembly as claimed in claim 20, wherein the gasket is mechanically attached to the frame by means of a plurality of clips in the gasket or the frame that engage corresponding engagement elements in the frame or the gasket respectively.

23. An assembly as claimed in claim 22, wherein the gasket is attached to the frame by means of a plurality of clips in the gasket that engage corresponding engagement elements in the frame.

24. An assembly as claimed in claim 20, wherein the fingers extend out of the plane of the sheet of metal and are forced toward the plane by the component.

25. An assembly as claimed in claim 20, wherein the clips and corresponding attachment elements are arranged so that they can be disengaged from one another by sliding in the plane of the sheet of metal.

26. An assembly as claimed in claim 20, wherein the clips are located on a pair of opposite peripheral regions of the gasket and can be disengaged from corresponding engagement elements by deforming the gasket into an arcuate configuration.

27. An assembly as claimed in claim 20, wherein the gasket has one or more apertures in a central region thereof.

28. An assembly as claimed in claim 20, wherein the resiliently deformable fingers are arranged at a spacing in the range of about 0.5 to 3 cm.

29. An assembly as claimed in claim 20, wherein the gasket is formed from a metal.
